(19) United States
(12) Patent Application Publication
(10) Pub. No.: US 2025/0329480 A1
(43) Pub. Date: Oct. 23, 2025

(54) PLURALITY OF SUPERCONDUCTING FILAMENTS

(71) Applicant: SUBRA A/S, Farum (DK)

(72) Inventor: Anders Christian WULFF, Farum (DK)

(21) Appl. No.: 18/870,915

(22) PCT Filed: Jun. 1, 2023
(86) PCT No.: PCT/EP2023/064749

§ 371 Date: Dec. 2, 2024

(30) Foreign Application Priority Data
Jun. 2, 2022 (EP) 22177004.3

(51) Int. Cl. H01B 12/06; H01B 12/08; H10N 60/01

(52) U.S. Cl. CPC H01B 12/06; H01B 12/08; H10N 60/0688; H10N 60/0801

(57) ABSTRACT

A method for forming a plurality of filaments, such that each filament is superconducting. The method includes providing a substrate having first and second sides. The substrate has a plurality of grooves in the first side of the substrate having a coating of a superconducting material so that for each groove within the plurality of grooves. A first part of the coating on a first side of a feature of the groove is separated from a second part of the coating on a second side of the feature of the groove. The second side of the feature of the groove is opposite of the first side of the groove, with removing from the second side of the substrate, at least a part of the substrate, to remove at least a connection from the first part of the coating to the second part of the coating via the substrate.

### FIELD OF THE INVENTION

The present invention relates to a method for forming a plurality of electrically conductive filaments, and more particularly relates to a plurality of superconducting filaments, and furthermore relates to a plurality of filaments and use thereof.

### BACKGROUND OF THE INVENTION

Superconducting structures may be seen as advantageous since they enable conducting current, such as direct current, without resistive electrical losses. Superconducting structures, such as superconducting tapes, are thus being used for several applications, such as electromagnets, generators and transformers. However, methods for forming superconducting structures may be complicated, not realistically applicable for industrial scale manufacture and although superconducting structures may possess excellent properties when carrying direct current, they may exhibit high energy losses when used in alternating current (AC) applications.

Hence, a method for forming superconducting structures, which enables reducing, minimizing, or eliminating losses when used in alternating current (AC) applications, which is simpler and/or increases an applicability for industrial scale manufacturing would be advantageous.

### SUMMARY OF THE INVENTION

It may be seen as an object of the present invention to provide a method for forming a plurality of filaments, a corresponding plurality of filaments and use thereof, such as for enabling reducing, minimizing or eliminating energy losses when used in for example alternating current (AC) applications, providing a method of manufacture which is simpler and/or increases an applicability for industrial scale manufacturing. It is a further object of the present invention to provide an alternative to the prior art.

Thus, the above-described object and several other objects are intended to be obtained in a first aspect of the invention by providing a method for forming a plurality of filaments, wherein each filament is superconducting, such as high-temperature superconducting (HTS), said method comprising, such as sequentially comprising:
Providing a substrate, such as wherein the substrate comprises metal, such as the substrate being a planar metal substrate, wherein the substrate has a first side and a second side, such as wherein the first side is opposite the second side, and wherein the substrate comprises a plurality of grooves in the first side of the substrate,
Applying on the substrate a coating, wherein the coating is comprising a superconducting material, such as a said coating being a multi-layer structure comprising a superconducting material optionally comprising rare-earth barium copper oxide (also referred to as REBCO), such as said coating being a superconductor stack, such as said coating being a high-temperature superconductor stack, so that for each groove within the plurality of grooves,
   i. a first part of the coating on a first side of a feature of the groove, such as the groove,
   is separated, such as disconnected, such as physically disconnected, from
   ii. a second part of the coating on a second side of the feature of the groove, such as the groove, wherein the second side of the feature of the groove is opposite of the first side of the feature of the groove,
Removing from the second side of the substrate, such as via electropolishing and/or etching, at least a part of the substrate, so as to remove at least a connection from the first part of the coating to the second part of the coating via the substrate, such as so as to provide the plurality of filaments, such as wherein portions of the substrate previously joining the filaments have been removed.

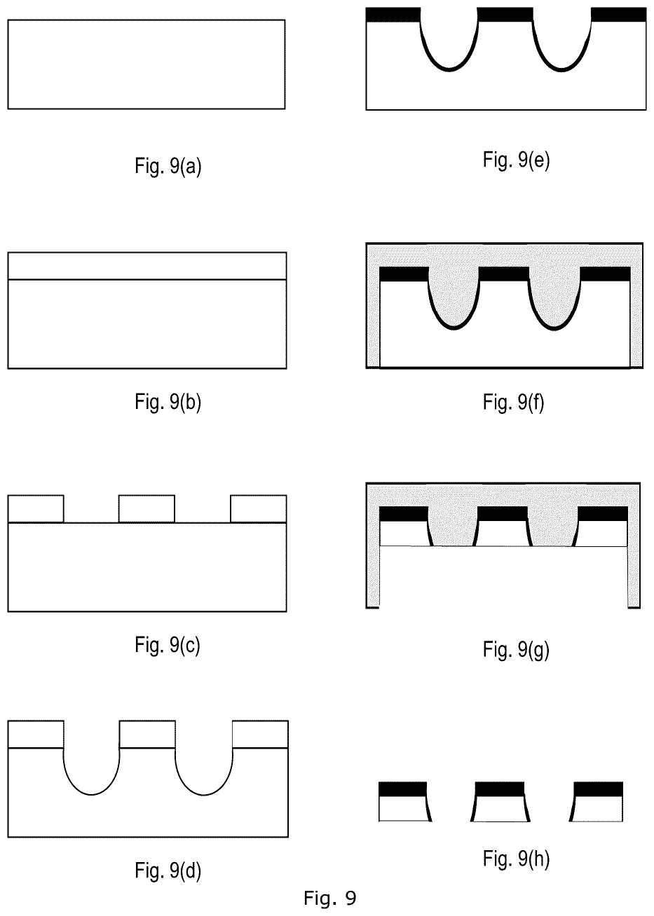

The invention may be particularly, but not exclusively, advantageous for providing a method for forming a plurality of filaments, which enables one or more of reducing, minimizing, or eliminating energy losses when used in alternating current (AC) applications, improving magnetic field stabilization, reducing magnetic field related forces, which is simpler and/or increases an applicability for industrial scale manufacturing. Another possible advantage may be that filaments may be provided, which are twistable, such as depicted in FIG. 9 in the peer-reviewed, academic review article “Multifilamentary coated conductors for ultra-high magnetic field applications”, Anders Christian Wulff et al., Supercond. Sci. Technol. 34 (2021) 053003, which is hereby incorporated by reference in entirety. The filaments may be twistable individually, in pairs or in bundles including more than two filaments.

In embodiments, the method comprises twisting the filaments individually, in pairs or in bundles including more than two filaments. An advantage may be that it enables minimizing energy losses, transposing (cf., e.g., the article “How filaments can reduce AC losses in HTS coated conductors: a review”, Francesco Grilli and Anna Kario, Supercond. Sci. Technol. 29 (2016) 083002 (15pp), which is hereby included by reference in entirety), and spatially (and statistically) distributing joints.

The present invention may be particularly advantageous as it provides a method for forming a wire or cable, made from high temperature, and/or ceramic based, superconductors with narrow, or fine, filaments.

By providing superconducting elements in the form of filaments, AC losses may be reduced, and magnets may be stabilized, such as described in the peer-reviewed, academic review article “Multifilamentary coated conductors for ultra-high magnetic field applications”, Anders Christian Wulff et al., Supercond. Sci. Technol. 34 (2021) 053003, which is hereby incorporated by reference in entirety, and/or in the peer-reviewed, academic article “How filaments can reduce AC losses in HTS coated conductors: a review” by Grilli and Kairo, Supercond. Sci. Technol. 29 (2016) 083002, which is also incorporated by reference in its entirety.

Another possible advantage of forming narrow superconducting filaments is that an effective capping or stabilization of the filament becomes possible, such as where the amount of capping, or stabilizing material, such as the fraction of stabilizing material, on the sides of the filament becomes significant or relatively larger (relative to a width of the filaments), e.g., in comparison to a wide flat tape typically with a width of several mm's, such as 2 to 12 mm. By increasing the cross-sectional fraction of stabilizer material relative to the corresponding fraction of superconductor layer, a superconducting tape/wire structure, which has more stabilizing material per area of superconducting material may be provided, and may therefore be more tolerant towards quenching, such as local heating, such as local loss of superconducting properties. Adding stabilizing material (such as a material chosen from the group comprising silver, copper, nickel, tin and/or zinc), such as silver, or copper, to the first and second side of the superconducting material may increase thermal and electrical stability of the superconducting material (such as composite). Adding stabilizing material on the edges of a standard wide tape does not significantly increase the stabilizer fraction to superconductor material fraction for a wide tape, such as a 4 mm or 12 mm, wide tape. For example: For a narrower tape, such as 70 um wide and 50 μm thick tape, 1 um HTS layer, adding 10 μm of stabilizer material on all faces of the tape yields an aspect ratio of stabilizer to HTS layer width of about 40, which is a factor of two (2) higher than that for a 12 mm wide and 50 μm thick tape with the same stabilizer layer thickness.

In an embodiment, the method further comprises adding a capping layer and/or a stabilizing material as a part of the coating and/or on top of the coating. ‘Capping layer’ and ‘stabilizing material’ is understood as is known in the art.

The method relies, such a necessitates and/or relies in embodiments exclusively, on method steps, which are applicable for large scale manufacture and/or is realistically applicable for industrial scale manufacturing, i.e., methods according to embodiments of the invention may be realistically applicable for industrial scale manufacturing. For example, each of the steps of providing a substrate, such as a tape provided in a reel-to-reel setup, optionally applying grooves, such as applying grooves in a rolling process and/or in a lithographic process (such as via photolithography and subsequent etching), applying a coating, optionally providing a resist and removing, such as etching from a backside, is a step, which may realistically be applied on an industrial scale.

It may be considered an insight of the present inventor, that a process for providing a plurality of superconducting filaments can be realized via, such as exclusively via, industrially applicable method steps.

It may furthermore be seen as an advantage, that methods according to embodiments of the invention are applicable, such as well-suited, for large-scale manufacturing, since they can be a relatively simple and/or efficient. For example, long filaments, optionally in large numbers may be obtained in a relatively fast manner and/or a manner demanding relatively few resources, such as relatively little equipment, manpower, energy and/or materials. Thus, large scale manufacturing may be possible with embodiments of the invention, and furthermore, this may be possible while minimizing resources, such as the use of resources.

Embodiments of the invention may furthermore be seen as effective in terms of enabling providing substrates for superconducting structures facilitating relatively large critical currents because it may be possible to obtain substrates with little or no damage zones (such as wherein a damage zone may be understood as a portion of superconducting material which is no longer functional, which is in turn may reduce the critical current).

A ‘filament’ is understood as is common in the art, such as an optionally flexible elongated element, such as a solid elongated element. By ‘elongated’ may be understood as referring to something having a larger dimension in a first direction (such as the direction referred to as the length direction), such as significantly longer, such as 2, 5, 10, 100, 1000, 10000 or 100000 times longer than the dimension in one or both of the other two directions (such as the directions referred to as width and height) orthogonal to the first direction. By ‘solid element’ may be understood an element comprising a solid phase, such as consisting of a solid phase.

‘Superconducting’ is understood as is common in the art, such as the capability of a material to conduct electrical current with substantially zero, such as zero, electrical resistance, optionally when cooled below a characteristic transition temperature.

‘Superconducting material’ is understood as is common in the art, such as in the context of ‘superconducting’ as described above in the preceding paragraph. The superconducting material may comprise, such as consist of, rare-earth barium copper oxide (also referred to as REBCO).

‘High-temperature superconducting (HTS)’ (or high-T_{c}) is understood as is common in the art, such as the capability of a material to be superconducting above a temperature of above 30 Kelvin, such above a temperature corresponding to the boiling point of liquid nitrogen, which is approximately 77 Kelvin.

By ‘substrate’ may be understood ‘a substrate suitable for supporting a superconducting element’ which in turn may be understood as a solid element upon which a superconducting material may be placed, such as deposited, so that the substrate and the superconducting element may together form a superconducting element. The substrate may comprise, such as consist of, one or more metallic elements (such as metals, semi-metals, semi-conductors, and/or metalloids) or alloys. The substrate may comprise, such as consist of, non-metals, such as one or more polymers. The substrate may comprise a substantially planar surface.

The solid element may have any shape, where shape is understood as the geometrical form as seen in a cross-section in a plane being orthogonal to a length axis (such as corresponding to an axis parallel with a direction in which current is to be carried), such as an arbitrary shape, such as any one of a tape-shape, a rectangular shape (such as a quadratic shape), a triangular shape, an ellipsoidal shape (such as a circular shape).

According to an embodiment, the method includes forming a Rutherford cable from a plurality of filaments.

Optionally the substrate is shaped so as to enable twist pitching, such as single element twisting, such pair twisting, such as a ROEBEL configuration (cf., the reference “Supercond. Sci. Technol. 22 (2009) 034003” which is hereby incorporated by reference in entirety), such as a Conductor On Round Core (cf. the reference “Supercond. Sci. Technol. 27 (2014) 125008” which is hereby incorporated by reference in entirety), or such as a geometry that enables transposition of superconducting elements placed on said substrate. Said shaping may be given by a piecewise linear shape, such as a zig-zag shape.

In embodiments, the substrate is a ‘tape’, i.e., an element which has thickness (length along a first dimension) which is significantly smaller, such as 10, 100 or 1000 times smaller, than its width (length along a second dimension) and where the width is significantly smaller, such as 10, 100, or 1000 times smaller, than its length (length along a third dimension).

The solid element may comprise any material selected from the group comprising: a nickel based alloy, a copper based alloy, a chrome based alloy, iron, aluminum, silicon, titanium, tungsten (also known as wolfram (W)), silver, Hastelloy, Inconel® and stainless steel.

By ‘Hastelloy’ is understood an alloy wherein the predominant alloying ingredient is nickel and wherein other alloying ingredients are added, such as the alloy comprising varying percentages of one or more of, such as all of, the elements: molybdenum, chromium, cobalt, iron, copper, manganese, titanium, zirconium, aluminum, carbon, and tungsten. In a particular embodiment, Hastelloy is an alloy which comprises the elements Ni, Cr, Fe, Mo, Co, W, C. In a more particular embodiment, the alloy also comprises Ni, Cr, Fe, Mo, Co, W, C and one or more of the elements Mn, Si, Cu, Ti, Zr, Al and B. In a more particular embodiment, the alloy is understood to comprise approximately 47 wt percent Ni, 22 wt percent Cr, 18 wt percent Fe, 9 wt percent Mo, 1.5 wt percent Co, 0.6 wt percent W, 0.10 wt percent C, less than 1 wt percent Mn, less than 1 wt percent Si and less than 0.008 wt percent B. Hastelloy may be referred to as “superalloy” or a “high-performance alloy” within the art.

‘Stainless steel’ is generally known in the art. In particular embodiments, there is provided stainless steel with nickel and/or chromium, such as to provide a stainless steel which is corrosion and/or oxidation resistant, mechanically stable and non-magnetic at the operation temperature of the superconducting layer.

‘Grooves’ are understood as is common in the art, such as an elongated depression, such as a depression with respect to adjoining portions of a substrate. A groove may serve to separate portions of a surface of a substrate into portions on either side of the groove so that deposition of material on top of the substrate, such as in a line-of-sight process, yields material portions, which are separated, such as disconnected, such as physically disconnected, by the groove. A possible advantage of such separation may be that a distance from the first side to the second (optionally planar) side of the substrate varies depending on position on the first side, which may in turn have the advantage that removal of material, e.g., in a spatially non-specific manner (e.g., where material is removed anywhere, such as removed in substantially equal amounts anywhere on an optionally planar surface), such as via etching or electropolishing, from the second side of the substrate may enable removing the full thickness of material from the first side to the second side of the substrate firstly at the positions of the grooves, i.e., portions with grooves can become disconnected from each other in a relatively simple and spatially non-specific removal step, e.g., via etching or electropolishing.

By a ‘line-of-sight’ process is understood any process which enables depositing material only on positions of a substrate which may be seen along a straight line from another position, such as a position above the substrate. ‘Line-of-sight’ process is thus construed broadly to comprise processes where the deposited material follows straight lines prior to deposition and processes for deposition which has a similar effect. In a particular embodiment, the line-of-sight process is any one of die coating, bubble jet coating and ink-jet coating. In particular embodiments, ‘line-of-sight’ is understood to be a process wherein the deposited material has its origin from a source and travels in a direct line therefrom to the position where it is deposited. In other words, there can only be deposited material on positions from which there can be drawn a straight line to the source which does not traverse any obstacles. A possible advantage of using a line-of-sight process may be that it enables depositing material on both sides of each groove, while utilizing a feature of the groove to shadow a portion, such as a bottom part of the groove, so that not deposition takes place at said portion, thereby forming a disruptive strip in the deposited material. By ‘disruptive strip’ may be understood a line of lack of coating material, which separates coating material into elongated strips of coating material on both sides of the disruptive strip. A disruptive strip may be seen as a gap in an otherwise coherent coating material. If a coherent coating material, such as a coherent layer of coating material, is traversed by a disruptive strip, the continuity of the coherent coating material is thus disrupted into two separate (layers of) material, such as two portions of coating material.

The grooves may be parallel with each other, such as parallel with each other. By ‘parallel’ may be understood parallel within 0, 1, 2, 3, 4, 5, 6, 7, 8, 9 or 10 degrees. It may be understood that the grooves may be piecewise parallel, such as the grooves themselves being non-rectilinear, such as curvilinear, such as piecewise linear, although immediately adjacent grooves may still be parallel.

‘Coating’ is understood as is common in the art, such as a layer, such as a thin layer, of material being applied to a substate. Application of the coating may be carried out in several ways, such as a line-of-sight process, such as anyone of die coating, bubble jet coating and ink jet coating. The coating may form, optionally with at least a part of the substrate, a 2nd generation high temperature superconductor coated conductor.

The structure and/or texture of the superconducting material in the coating may be endowed to the superconducting layer via the substrate and/or via another layer in the coating, such as a buffer layer.

A ‘buffer (layer)’ is understood as is common in the art, and may for example be understood to optionally provide structure and/or texture to the superconducting layer and/or may for example be understood to provide an optionally inert chemical barrier.

By a ‘superconductor stack’ may be understood a layered construction, such as a multi-layer structure, optionally with distinct layers, comprising a buffer layer (e.g., 0.1-2 micrometer) and a superconducting layer (e.g., rare-earth-based barium copper oxide (REBCO) of thickness being, e.g., 1-5 micrometer). The superconductor stack may be a high-temperature superconductor stack.

By ‘a first side of a feature of the groove’ is understood an area on only one side of the feature of the groove.

By ‘feature of the groove’ is understood a portion of the groove or the groove in entirety. For example, the groove in entirety may serve to separate, such as disconnect, such as physically disconnect, portions of coating material applied in a line-of-sight process from directly above the groove (in which example there will be a portion on either side of the groove, wherein neither of these portions comprise material in the groove). In another example, an edge of the groove or a side of the groove may serve to separate, such as disconnect, such as physically disconnect, portions of coating material applied in a line-of-sight process from a position outside of a plane being orthogonal to a surface comprising the groove and parallel with the groove (in which example one portion of the coating may comprise material in the groove, such as in the bottom of the groove).

By ‘separated’ may be understood that elements being separated are spatially separated, such as the elements being separated by another material than the material of the elements, e.g., by having non-solid material between the elements. In embodiments, separated elements may be connected to each other via material identical to the material of the elements (e.g., portions of elements on tops of protrusions/hills on each side of a groove may be separated from each other but connected via material identical to the material of the elements extending via the groove from one protrusion/hill to the other protrusion/hill). In embodiments, separated elements may be disconnected, such as physically disconnected, from each other, due to absence of material identical to the material of the elements between the elements (e.g., elements on tops of protrusions/hills on each side of a groove may be separated from each other and physically disconnected due to no material identical to the material of the elements extending from one protrusion/hill to the other protrusion/hill).

By ‘disconnected’ may be understood physically and/or electrically disconnected, such as wherein disconnected elements are not electrically connected by an electrically conducting material and/or not physically connected by the material of the elements.

By ‘removing from the second side of the substrate’ is understood that material is removed from the surface of the second side of the substrate, such as from a backside of the substrate with respect to a frontside comprising grooves, such as sequentially removing, such as removing in each of a plurality of steps (which can follow-each other in a substantially continuous manner, such as by etching, or can be discretized, such as when moving material in a plurality if milling or grinding steps) the outermost material. It may furthermore be understood, that removing of material from the second side of the substrate comprises removing material from the second side of the substrate prior to removing material from a first side of the substrate and/or while there is still material on the first side of the substrate. When removing material from the second side of the substrate, a position of the surface of the second side of the substrate moves towards the first side of the substrate and/or the portions of coating.

By ‘remove at least a connection from the first part of the coating to the second part of the coating via the substrate’ may be understood that material of the substrate is removed so that there subsequently is no physical connection via the substrate from first part of the coating to the second part of the coating, such as the first part of the coating and the second part of the coating become detachable or detached from each other and/or whereby the first and second parts of the coating are no longer connected via the substrate, such as at least in a cross-sectional plane being orthogonal to a longitudinal direction of one or more or all filaments, such as for any part of the substrate, there is no path through the substrate from the first part of the coating to the second part of the coating.

In embodiments, ‘remove at least a connection from the first part of the coating to the second part of the coating via the substrate’ comprises splitting or breaking or severing or rupturing at least a connection from the first part of the coating to the second part of the coating via the substrate.

Removal of material may take place via, e.g., electropolishing and/or etching (such as electro-etching), a grinding process, a cutting process or a laser process.

A step of ‘removing from the second side of the substrate at least a part of the substrate’ may be carried out via electropolishing and/or etching, such as electro-etching. A possible advantage may be that electropolishing and/or etching are well-established, applicable on an industrial scale and/or applicable for removing some material (such as the substrate) while being gentle on remaining materials (such as the coating, in particular if said remaining materials are covered with a protective covering).

By ‘etching’, ‘electro-etching’ or ‘electropolishing’ may be understood removal of (substrate) material by etching, electro-etching or electropolishing, such as with an etchant. The etchant may in particular embodiments be in any one of the following states of matter: plasma, liquid and gas. In a particular embodiment Reactive Ion Etching (RIE) is employed.

By ‘a grinding process’ is understood that a portion of the (substrate) material is removed by a grinding process or a polishing process, such as repeatedly scraping off minor portions of the (substrate) material to be removed. A ‘polishing process’ is understood to be similar to a ‘grinding process’ in the present context.

By a ‘cutting process’ is understood a process wherein material is displaced, such displaced rather than removed. This may be achieved using a relatively sharp tool.

A step of ‘removing from the second side of the substrate at least a part of the substrate’ may be carried out with a laser process, such as via laser marking and/or any one of laser engraving, laser etching and laser annealing.

It may be an advantage, e.g., when using spatially specific or spatially well-defined or spatially well-definable methods (such as wherein material is removed or removable at spatially well-defined position, such as even on a planar surface, such as material at two positions with similar topography being removed at significantly different rates, such as wherein the rate of removal at one position being non-zero and the other being substantially zero), such as laser marking, that the grooves enable that a smaller distance from the first side to the second side (at positions corresponding to the bottom of the grooves) in turn enables that less substrate material must be removed (compared to a situation without grooves) to penetrate the substrate.

According to an embodiment, there is presented a method further comprising prior to removing from the second side of the substrate at least a part of the substrate:
Applying on some or all of the first part of the coating and on some or all of the second part of the coating, such as on the first part and/or the second part of the coating, a protective covering, such as a resist, such as a protective covering layer, such as wherein the protective covering layer partially or wholly fills vacant space in the grooves.

By ‘protective covering’ may be understood a layer of material, such as a resist, which can protect (e.g., protect against mechanical deformation and/or thermal effects) underlying material, such as a coating, e.g., during the step of removing from the second side of the substrate at least a part of the substrate, such as during etching. An advantage of applying a protective covering may be that the materials upon which it is applied may suffer less, such as no, damage, during a step of removing from the second side of the substrate at least a part of the substrate, which may in turn go to reduce, minimize or eliminate a deterioration of superconducting properties of the resulting filaments. The protective covering could be a photoresist, such as a liquid photoresist.

According to an embodiment, there is presented a method wherein the method is further comprising subsequent to removing from the second side of the substrate at least a part of the substrate:
Removing the protective covering partially or wholly from some or all of the coating and remaining portions of the substrate, such as so as to remove at least a connection from the first part of the coating to the second part of the coating via the protective covering.

An advantage of removing the protective covering may be that it enables separating the filaments and/or enables working with the filaments, e.g., for the purpose of constructing a (optionally twisted and/or transposed), multi-filament superconducting element or a multi- filament superconducting wire, without the protective covering getting in the way (optionally wherein the individual filaments can be twisted pair-wise, and/or can be transposed with respect to adjacent filaments).

According to an embodiment, there is presented a method wherein ‘removing the protective covering partially’ is carried out via electropolishing and/or etching, such as electro-etching or physical etching. A possible advantage may be that electropolishing and/or etching are well-established, applicable on an industrial scale and/or applicable for removing some material (such as the substrate) while being gentle on remaining materials (such as the coating, in particular if said remaining materials are covered with a protective covering).

According to an embodiment, there is presented a method wherein the method comprises providing the substrate by:
Providing a substrate without grooves in the first side of the substrate, and
forming the plurality of grooves in the first side of the substrate.

The ‘forming the plurality of grooves’ can be carried out in several ways, such as by cutting or roll-cutting, which may be beneficial for industrial scape applicability.

According to an embodiment, there is presented a method wherein forming the plurality of grooves in the first side of the substrate comprises forming the plurality of grooves in the first side of the substrate in a reel-to-reel setup. A possible advantage may be that it facilitates large-scale processing.

According to an embodiment, there is presented a method wherein the removing from the second side of the substrate at least a part of the substrate, such as the electropolishing and/or etching, is stopped while each part of the coating, such as the first part of the coating and the second part of the coating, is adjoining a remaining part of the substrate. An advantage may be that by having each part of the coating is adjoining a remaining part of the substrate, may be that the remaining part of the substrate endows mechanical strength to the filament comprising coating and remaining part of the substrate. In some embodiments, the substrate is a roll-processed substrate, which may render the corresponding in increase in strength larger and possibly larger than an increase in strength given by adding material to a coating wherein the (original) substrate has been removed completely. Another possible advantage of stopping may be that a substrate is provided, i.e., a step of providing, e.g., by deposition, of a substrate is dispensed with.

Another possible advantage is that the coating, such as the superconductor stack optionally including a protective capping and/or a stabilizer material, is well adhered to the optionally metallic substrate. For example, a superconducting stack in a coated conductor production may be epitaxially grown on a metallic substrate, which may be providing a good mechanical strength between the metallic substrate, buffer layers in the superconducting stack and the superconducting layer. Good mechanical strength may be advantageous for avoiding cracks in the coating, which may in turn be advantageous for avoiding fracturing of the coating.

According to an embodiment, there is presented a method wherein the electropolishing and/or etching is stopped before a liquid utilized for said electropolishing and/or etching reaches the first part of the coating and/or the second part of the coating. A possible advantage may be that it is avoided that said liquid reaches the first part of the coating and/or the second part of the coating. A reason this could be advantageous relative to a situation wherein said liquid reaches the first part of the coating and/or the second part of the coating, is that if contact is made between the liquid and the first part of the coating and/or the second part of the coating, then properties of the first part of the coating and/or the second part of the coating, such as the superconducting material of the first part of the coating and/or the second part of the coating, may be changed, such as degraded. A further possible advantage may be that if the electropolishing and/or etching is stopped before a liquid utilized for said electropolishing and/or etching reaches the first part of the coating and/or the second part of the coating, then said liquid cannot move within the first part of the coating and/or the second part of the coating (which may be porous). In embodiments, undercuts at the grooves may be utilized to ensure that deposited superconducting material (of the first part of the coating and/or the second part of the coating) does not extend to the sides of the grooves and form a coherent structure of superconducting material extending from one side of a feature of a groove to another side of the feature, such as from a top portion (protrusion) of the substrate adjacent to a groove to a side of a groove or even to a bottom of a groove. A coherent structure of superconducting material with a part on a top portion (protrusion) of the substrate adjacent to a groove may thus be farther away from the second side of the substrate (such as wherein a distance between the second side of the substrate and the point of the coherent structure being closest to the second side of the substrate), e.g., as compared to a situation without undercut. The undercut may serve to provide a physical disconnection between (sacrificial) superconducting material at one side of a feature of a groove, e.g., at the bottom of the groove, and superconducting material at another side of a feature of a groove, such as on a top portion (protrusion) of the substrate next to a groove.

According to an embodiment, there is presented a method, wherein removing from the second side of the substrate at least a part of the substrate is carried out via grinding and/or laser. Possible advantages of grinding may be that it is efficient, cost-effective, fast and/or scalable. Possible advantages of laser may be that it is cost-effective, controllable and/or spatially well- definable.

According to an embodiment, there is presented a method, wherein each groove in the plurality of grooves comprises one or more undercuts. This may be beneficial for enabling deposition of superconducting material on the substrate and utilizing the one or more undercuts to provide physical disconnection between parts of superconducting material.

According to an embodiment, there is presented a method wherein the method is further comprising:
Forming, such as via etching, one or more undercuts at each groove, such as forming the one or more undercuts in a two-level undercut process (2LUPS).

An undercut may be formed, e.g., by etching and/or electropolishing, such as is described in, e.g., WO13174380A1, which is hereby incorporated by reference in entirety. By ‘undercuts’ may be understood volumes at each groove, which volumes may be below remaining portions of the substrate. Thus, an undercut (volume) may be shadowed by overhanging portions of the substrate. An advantage is that when a material is deposited on substrate comprising grooves with undercut(s) using a line-of-sight process from above the groove, the material is not deposited on the portions of the shadowed undercut portions of the substrate. By a two-level undercut-profile substrate (2LUPS) process may be understood providing undercuts in a process comprising a sandwich structure, wherein disruptive strips are formed in an outer layer, such as is described, e.g., in WO13174380A1, which is hereby incorporated in entirety, more particularly in FIGS. 3A-3H and accompanying description in WO13174380A1, which is hereby incorporated by reference. The 2LUPS process is alternatively or additionally described in the article “Multifilamentary coated conductors for ultra-high magnetic field applications”, Anders Christian Wulff et al., Supercond. Sci. Technol. 34 (2021) 053003, which is hereby incorporated by reference in entirety, such as in particular in section 4.2.

According to an embodiment, there is presented a method wherein the method is further comprising:
Twisting the plurality of filaments, or multiple pluralities of filaments, wherein each filament is twisted around its own axis and/or wherein a plurality of filaments are twisted around their common axis, such as wherein optionally twisted bundles of filaments are twisted around each other, thereby providing one or more superconducting structures each comprising a plurality of twisted filaments, such as wherein each filament has a helical shape with a centre axis within one or more other helical shaped filaments, and/or.
Transposition of the plurality of filaments, or multiple pluralities of filaments thereby providing one or more superconducting structures each comprising a plurality of transposed filaments.

By ‘twisting’ may be understood that one portion, such as an end, of the filament is rotated around a longitudinal axis with respect to another portion, such as the opposite end, such as wherein said rotation spans at least half a revolution or pi (radians) or 180 degrees, such as n times pi, where n is at least 1, such as at least 2 (corresponding to at least a full revolution or at least 360 degrees), such as at least 5, such as at least 10, such as at least 50, such as at least 100, such as at least 1000. Twisting may take place for each filament around its own axis and/or for a plurality (such as a bundle) of filaments, which are twisted together. An advantage of twisting may be that it enables reducing, minimizing or eliminating instability and coupling loss. Transposition of filaments may effectively decouple the filaments and this may be obtained by twisting of the filaments (cf., e.g., the article “How filaments can reduce AC losses in HTS coated conductors: a review”, Francesco Grilli and Anna Kario, Supercond. Sci. Technol. 29 (2016) 083002 (15pp), which is hereby included by reference in entirety, and where reference is in particular made to the end of section 2 on p. 3).

By ‘transposition’ may generally be understood the optionally periodic swapping of positions of the conductors of a transmission line, such as in order to reduce crosstalk and/or otherwise improve transmission, cf., e.g., the article “How filaments can reduce AC losses in HTS coated conductors: a review”, Francesco Grilli and Anna Kario, Supercond. Sci. Technol. 29 (2016) 083002 (15pp), which is hereby included by reference in entirety).

It may furthermore be advantageous to deposit an additional capping, such as metal, such as copper or silver, such as silver, before the individual filaments are twisted around their own axis (longitudinal, rolling axis). The capping can also be added after twisting, and/or, after transposing and/or twisting with other filaments. The extra capping provides additional mechanical and thermal stabilization. Metallization can be applied using electrodeposition, such as plating, or sputtering.

According to an embodiment, there is presented a method wherein the method is further comprising:
Forming a superconducting wire by providing one or more superconducting structures with a core and/or a capping.

A ‘core’ may be understood to be a centrally placed optionally metallic (such as copper, stainless steel, gold or silver) element, optionally wherein the one or more superconducting structures are twisted around the core. An advantage of a core may be that it yields mechanical strength to the resulting superconducting wire.

A ‘capping’ may be understood as a peripherally placed material. An advantage of a capping may be that it yields mechanical and/or thermal protection of the superconducting portions of the resulting superconducting wire. Another possible advantage of a capping may be that it yields additional/extra mechanical strength to the resulting superconducting wire. It may also provide extra thermal heat capacity, which may serve to protect against superconductor quenching (see “Multifilamentary coated conductors for ultra-high magnetic field applications”, Anders Christian Wulff et al., Supercond. Sci. Technol. 34 (2021) 053003, which is hereby incorporated by reference in entirety)

By ‘wire’ is understood an electrically conducting and optionally flexible element comprising a plurality of superconducting filaments and one or more additional elements, such as a capping and/or a core. The wire may comprise at least 5 filaments, such as at least 10 filaments, such as at least 100 filaments, such as at least 500 filaments, such as at least 1000 filaments, such as at least 10000 filaments. A length of the wire may be at least 0.1 m, such as at least 1 m, such as at least 10 m, such as at least 100 m, such as at least 1000 m.

According to an embodiment, there is presented a method wherein the method is further comprising forming a coil by coiling up one or more filaments, superconducting structures and/or superconducting wires. An advantage of providing a coil, is that such coil may be useful for numerous purposes, e.g., generating a magnetic field, such as is used in Nuclear Magnetic Resonance (NMR) scanners, Magnetic Resonance Imaging scanners, fusion reactor poloidal or toroidal field magnets, central column solenoid magnets, toroids, solenoids, accelerator magnets, or race track coil magnets.

According to an embodiment, there is presented a method wherein the superconducting wire comprises a reinforcing element, such as a reinforcing element comprising Hastelloy and/or carbon fibers, and wherein the reinforcing element is optionally embedded in a capping. A possible advantage may be increased strength of the resulting superconducting wire. The reinforcing element may be a fibrous material (optionally having a diameter of 50-500 micrometer, such as 100-300 micrometer, such as 150-250 micrometer, such as substantially 200 micrometer), such as a Hastelloy-fiber or a carbon-fiber wrapped or coiled around one or more filaments, and optionally embedded in a capping, optionally by being plated into the capping, such as a copper capping, such as produced by copper plating.

According to an embodiment, there is presented a method, wherein a distance between a plane being parallel with a surface of the first side of the substrate, such as being tangential with the protrusions, such as the top of the protrusions, between the grooves, and a plane being tangential to a bottom of the plurality of grooves, such as a depth of the grooves as measured in a direction orthogonal to the plane of the first side of the substrate, is at least 1 μm, such as at least 10 μm, such as at least 25 μm, such as at least 50 μm, such as at least 100 μm. By having a minimum distance (depth) a tolerance for subsequent removing of the substrate is correspondingly large. This may in turn simplify said step of removing and/or reduce a risk of failure or damages to the remaining elements.

According to an embodiment, there is presented a method, wherein providing a substrate comprises providing the substrate, such as a tape, in a reel-to-reel setup. A possible advantage may be that it facilitates large-scale processing.

According to an embodiment, there is presented a method, wherein applying on the substrate a coating comprises applying on the substrate, such as a tape, a coating in a reel-to-reel setup. A possible advantage may be that it facilitates large-scale processing.

According to an embodiment, there is presented a method, wherein removing from the second side of the substrate at least a part of the substrate comprises removing (such as removing via any one or more of electropolishing, etching, grinding and/or laser) from the second side of the substrate at least a part of the substrate, such as a tape, in a reel-to-reel setup. A possible advantage may be that it facilitates large-scale processing.

According to a second aspect of the invention, there is presented a plurality of filaments, wherein each filament is superconducting, such as high-temperature superconducting (HTS), and wherein each filament is not being connected to the one or more other filaments via the substrate, such as wherein each filament is physically disconnected from one or more other parts of the substrate (such as where each filament comprises a substrate, such as a part of the (original) substrate).

According to an alternative second aspect of the invention, which replace the second aspect of the invention, there is presented a plurality of filaments, wherein each filament is superconducting, such as high-temperature superconducting (HTS), and wherein each filament is not being connected to the one or more other filaments via a substrate, such as wherein each filament is physically disconnected from one or more other parts of the substrate.

According to an embodiment, there is presented a plurality of filaments, where each filament comprises a substrate. A possible advantage may be that this goes to increase the strength and/or robustness of the filament. This may, for example, be utilized when the filament is integrated into a wire.

According to an embodiment, there is presented a plurality of filaments, wherein the substrate is a solid element upon which a superconducting material may be placed, such as deposited, so that the substrate and the superconducting element may together form a superconducting element.

According to an embodiment, there is presented a plurality of filaments, wherein the solid element comprises a material selected from the group comprising: a nickel based alloy, a copper based alloy, a chrome based alloy, iron, aluminum, silicon, titanium, tungsten (also known as wolfram (W)), silver, Hastelloy, Inconel® and stainless steel.

According to an embodiment, there is presented a plurality of filaments, wherein each filament is comprising superconducting material comprising, such as consisting of, rare-earth barium copper oxide.

According to an embodiment, there is presented a plurality of filaments wherein each filament is comprising superconducting material, such as high-temperature superconducting (HTS) material, and furthermore comprising (such as comprising after a step of removing from the second side of the substrate at least a part of the substrate has ended) a part of the substrate adjoining the superconducting material, and optionally furthermore comprising a buffer layer and/or one or more metallic layer (which may together be seen as forming a superconductor stack, such as an HTS stack).

According to an embodiment, there is presented a plurality of filaments, wherein each filament comprises superconducting material on, such as partially or fully covering each of, two or more sides of the substrate, such as wherein each of said sides are non-parallel, such as orthogonal, with respect to at least one other side within the two or more sides as observed in a cross-sectional view orthogonal to a longitudinal direction of each of the filament. A possible advantage may be that a larger area of each filament (such as not merely a top side) may be utilized for carrying superconducting material, which may in turn enable each filament to carry more current.

According to an embodiment each filament comprises superconducting material wherein an angular extent of the superconducting material as observed in a cross-sectional view orthogonal to a longitudinal direction of each of the filament around a geometrical centre of the substrate is 90° or more, such as at least 135°, such as 180° or more, such as more than 181°, such as more than 185°, such as more than 190°, such as more than 200°, such as at least 225°, such as at least 270°, such as at least 315°. As an example, for a filament with a quadratic cross-section having superconducting material only on one side, the angular extent would be 90°. As another example, for a filament with a circular cross-section having superconducting material only on one side (such as an upper side, cf., e.g., the northern hemisphere for a cross-section through the middle of a globe) the angular extent would be 180°. An advantage of a relatively large angular extent may be that a larger part of the surface of the filament is utilized for carrying superconducting material, which in turn may enable carrying more current. In embodiments, the angular extent is less than 360° (such as not fully encircling, such as less than 355°.

According to an embodiment, there is presented a plurality of filaments wherein the substrate is roll-processed, such as metal or metal-alloy, such as Hastelloy, stainless steel, wherein an austenitic nickel-chromium-based superalloys, such as Inconel®, or nickel-tungsten. An advantage of a roll-processed, such as warm-or cold-roll-processed, metal or metal-alloy may be that it has a high strength, such as a high strength with respect to materials, such as metals or metal-alloys, which are deposited, e.g., via E-beam evaporation, thermal evaporation, sputter deposition or electrochemical deposition. In an embodiment, the substrate is annealed, such as subjected to a heat-treatment, subsequent to being roll-processed. A roll-processed (substrate) material will have a characteristic grain structure, which is visible, e.g., in a scanning electron microscope (SEM).

According to an embodiment, there is presented a plurality of filaments wherein the plurality of filaments are connected by a protective covering, and where the protective covering is only partially covering each filament, such as covering a superconducting coating but not all of the remainder of the filament. An advantage of having a protective covering may be that a part of the filament, such as a superconducting coating, can be protected, e.g., during storage and transport. Another possible advantage is that the protective covering can serve to hold the filaments together in a fixed spatial relationship, such as to as to maintain control over the filaments relative spatial positioning.

According to an embodiment, there is presented a plurality of filaments wherein a width, such as a maximum dimension in a direction orthogonal to a longitudinal direction of each filament and optionally furthermore being parallel with an interface between superconducting material and substrate material, of each filament is equal to or less than 2 mm, such as equal to or less than 1 mm, such as equal to or less than 750 micrometer, such as equal to or less than 500 micrometer, such as equal to or less than 400 micrometer, such as equal to or less than 300 micrometer, such as equal to or less than 250 micrometer, such as equal to or less than 200 micrometer, such as equal to or less than 150 micrometer, such as equal to or less than 100 micrometer. An advantage of a relatively small width may be that it enables having multiple filamented superconductors in a superconducting structure, which may go to reduce or minimize the screening field magnitude for each filament and/or hysteresis energy losses (Qₕ). Another advantage is that mechanical bending, including twisting around the longitudinal axis of the filaments, becomes easier the more narrow the filaments are. A possible advantage of twisting may in turn be that it enables transposition (such as transposition) with reduced, minimal or zero in-plane bending relative to in-plane bending for wider filaments (where in-plane bending may in general be disadvantageous, such as degrades the superconducting properties). Another possible advantage is that the fraction of metal capping per individual filament increases and thus increases the thermal stabilization. Another possible advantage is that smaller filaments reduce the amount of Joule heating in case of rupture/breakdown of a single filament.

A width of a filament may be understood to be a dimension in a direction orthogonal to a longitudinal direction of each filament and being parallel with an interface between superconducting material and substrate material.

According to an embodiment, there is presented a plurality of filaments wherein a width, such as a maximum dimension in a direction orthogonal to a longitudinal direction of each filament and optionally furthermore being parallel with an interface between superconducting material and substrate material, of each filament is equal to or less than 200 micrometer, such as equal to or less than 150 micrometer, such as equal to or less than 100 micrometer, such as equal to or less than 50 micrometer, such as equal to or less than 25 micrometer, such as equal to or less than 10 micrometer.

According to an embodiment, there is presented a plurality of filaments wherein a width, such as a maximum dimension in a direction orthogonal to a longitudinal direction of each filament and optionally furthermore being parallel with an interface between superconducting material and substrate material, of each filament is equal to or more than 1 micrometer, such as equal to or more than 10 micrometer, such as equal to or more than 25 micrometer, such as equal to or more than 50 micrometer, such as equal to or more than 100 micrometer, such as equal to or more than 200 micrometer, such as equal to or more than 500 micrometer. A possible advantage is that this minimum width may be advantageous for overcoming an issue of grain size (of e.g., REBCO with grain sizes of ca. 50 nm) becoming comparable to the width. Another possible advantage may be that it allows dissipation of current into surrounding materials, such as a cupper matrix.

According to an embodiment, there is presented a plurality of filaments wherein a length, such as a maximum dimension in a longitudinal direction of each filament, of each filament is equal to or larger than 1 m, such as equal to or larger than 10 m, such as equal to or larger than 100 m, such as equal to or larger than 1 km, such as equal to or larger than 10 km, such as equal to or larger than 100 km, such as equal to or larger than 1000 km. The length of each filament may be understood as the largest dimension of the filament. It may be understood, that the length is to be measured along the filament and/or for the configuration of the filament wherein the length is maximum (such as for example the length of a filament would be the length of the rolled out filament rather than a length or diameter of a coil comprised a rolled-up filament). The length may in particular embodiments be 1 m, such as 100 m, such as 1 km, such as 20 km, such as 100 km, such as above 100 km, such as within 1 m-30 km, such as within 1 km-30 km.

According to an embodiment, there is presented a plurality of filaments wherein a length, such as a maximum dimension in a longitudinal direction of each filament, of each filament is equal to or less than 1 km, such as equal to or less than 100 m, such as equal to or less than 25 m, such as equal to or less than 10 m.

A possible advantage of relatively shorter length of filament sections may be that, e.g., shorter pieces of manufactured coated conductors, such HTS tapes, in e.g. 4 mm width or 12 mm width, and in lengths of, e.g., 100 m can be spliced together. The splicing section can span lengths such as 1-100 cm, such as 10 cm or 50 cm, or several meters, such as 1-10 m, such as 1 m or 5 m. The splicing can be produced industrially by electrodeposition, such as copper plating, such as silver plating, or soldering, such as Sn soldering. The filaments can be mechanically twisted into to a transposing matrix and then, e.g., copper plated, or soldered, to adhere to the filaments. The longer the splicing section, the lower the electrical resistance across the splicing, or joint. This solution solves the problem for joining superconducting (SC), such as HTS, tapes where the tapes are typically soldered together only in local short sections at tape ends. Using shorter pieces from SC, such as HTS, manufacturing possibly enables complete, or partial, overlapping of joining sections over, e.g., several meters meaning that joints will no longer constitute a so-called weak point. Using shorter production pieces from the HTS manufacturing simplifies the coated conductor production and allows a larger superconductor performance span because the multifilaments can be transposed along the entire length of a superconducting wire, or cable, with a variation in the individual filament quality, such as superconductor performance, as long as individual filaments with low, mid and high performance (e.g. Ic or Tc) are distributed evenly, i.e. statistically distributed evenly along the entire wire or cable length.

This means that the multifilament transposed wire, or cable, can be produced with a generally lower HTS production criteria, and may even benefit from employing HTS tapes from different vendors, such as with a variation in superconducting performance level providing a levelized performance along the entire wire.

According to an embodiment, there is presented a plurality of filaments, wherein a thickness, such as a maximum dimension in a direction orthogonal to a longitudinal direction of each filament and optionally furthermore being orthogonal to an interface between superconducting material and substrate material, such as wherein said dimension is being orthogonal to one or both of the dimensions along which width and length are measured, is at least 1 μm, such as at least 10 μm, such as at least 25 μm, such as at least 50 μm, such as at least 100 μm, such as at least 200 μm, such as at least 500 μm. A possible advantage may be that such dimension yields strength and/or robustness. Such dimension may be provided via a method according to the first aspect with a corresponding depth of grooves and a homogeneous etch. Alternatively, such dimension may be provided via a method according to the first aspect with a spatially confined etch.

A thickness of a filament may be understood to be a dimension in a direction orthogonal to a longitudinal direction of each filament and being orthogonal to an interface between superconducting material and substrate material.

According to an embodiment, there is presented a plurality of filaments wherein an engineering current density JE of each filament at a temperature of 77 Kelvin and at zero applied magnetic field is at least 10⁵ A/cm², such as at least 3*10⁵ A/cm², such as at least 5*10⁵ A/cm², such as at least 10⁶ A/cm², such as at least 3*10⁶ A/cm², such as at least 10⁷ A/cm², wherein the engineering current density is defined as the current density for a cross-sectional area including superconducting material and substrate including if present buffer layer or buffer-stack and stabilizing layer, wherein each filament is optionally having a width being equal to or less than 500 micrometer, such as equal to or less than 400 micrometer, such as equal to or less than 300 micrometer, such as equal to or less than 250 micrometer, such as equal to or less than 200 micrometer, such as equal to or less than 150 micrometer, such as equal to or less than 100 micrometer. ‘Engineering current density’ is understood as is common in the art.

An example of a width of a superconducting filament is 20 μm

According to an embodiment, there is presented a plurality of filaments wherein a distance, such as an average distance, from an edge, such as an edge at a side, of the filament and into the filament, wherein superconducting properties of the superconducting material has deteriorated, is equal to or less than 100 micrometer, such as equal to or less than 50 micrometer, such as equal to or less than 25 micrometer, such as equal to or less than 20 micrometer, such as equal to or less than 15 micrometer, such as equal to or less than 10 micrometer, such as equal to or less than 5 micrometer, such as equal to or less than 1 micrometer. By ‘deteriorated’ is understood a change of properties affecting negatively the superconducting properties, such as delamination, phase change and/or cracking. The distance can be observed and measured, e.g., via scanning electron microscopy (SEM) images obtained, e.g., from above the superconducting coating portions and/or in cross-sectional images obtained from cross-sectional planes being orthogonal to a longitudinal direction of the filaments. An advantage is that a relatively small distance of deterioration may go to maintain a relatively high engineering current density.

It is considered advantageous to have no, or as few cracks as possible, as cracks may lead to fracture of the coating, such a wherein the coating is comprising a high-temperature superconducting (HTS) layer.

According to an embodiment, there is presented a plurality of filaments wherein a ratio t/w of thickness t (with thickness optionally being measured in a direction orthogonal to a longitudinal direction and orthogonal to an interface between a superconducting coating and substrate) over width w (with width optionally being measured in a direction orthogonal to a longitudinal direction and orthogonal to a thickness direction and/or orthogonal to an interface between superconducting material and substrate material) of the substrate adjoining the superconducting material is at most equal to or less than 20:1, such as equal to or less than 10:1, such as equal to or less than 5:1, such as equal to or less than 2:1. It may be an advantage to have a relatively low ratio t/w of width over thickness, for example due to a low ratio rendering the integration of filaments into a superconducting structure simpler.

According to a third aspect of the invention, there is presented use of the plurality of filaments as provided according to the first aspect and/or according to the second aspect for conducting a current, such as conducting a current at superconducting conditions.

According to a fourth aspect of the invention, there is presented a wire, such as a cable (such as comprising a plurality of wires), such as a power cable (such as a cable capable of transmitting electrical power at at least 10 kV and/or transmitting a current of at least 100 Ampere), comprising the plurality of filaments provided according to the first aspect and/or according to the second aspect. By ‘cable’ is understood a conducting structure comprising the plurality of wires, such as wherein the wires are twisted around their own axis and/or a common axis. A length of the cable may be at least 0.1 m, such as at least 1 m, such as at least 10 m, such as at least 100 m, such as at least 1000 m. The cable may comprise at least 5 filaments, such as at least 10 filaments, such as at least 100 filaments, such as at least 500 filaments, such as at least 1000 filaments, such as at least 10000 filaments.

According to alternative for further aspects of the invention, there is presented any of a coil, an electrical generator, a transformer, Nuclear Magnetic Resonance (NMR) scanners, Magnetic Resonance Imaging scanners, fusion reactor poloidal or toroidal field magnets, central column solenoid magnets, toroids, solenoids, accelerator magnets, or race-track coil magnets, comprising the plurality of filaments provided according to the first aspect and/or according to the second aspect

### BRIEF DESCRIPTION OF DRAWNGS

The first, second, and third aspect according to the invention will now be described in more detail with regard to the accompanying figures. The figures show one way of implementing the present invention and is not to be construed as being limiting to other possible embodiments falling within the scope of the attached claim set.

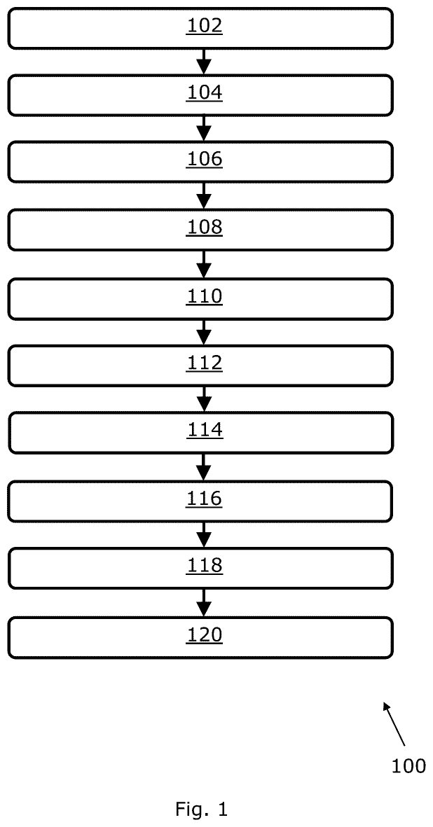

FIG. 1 is a flowchart illustrating a method according to an embodiment of the invention.

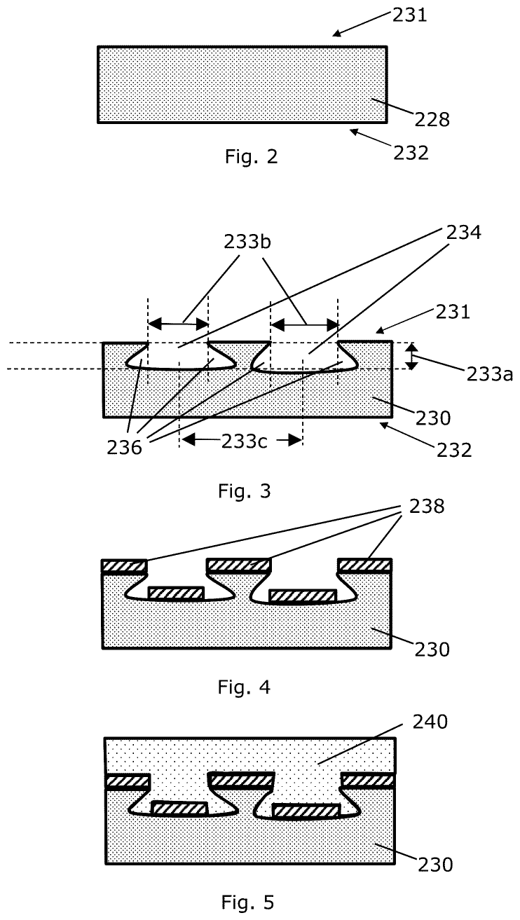

FIGS. 2-7 shows schematic illustrations depicting steps in a method according to an embodiment of the invention.

FIG. 8 shows a superconducting wire.

FIG. 9 illustrates a method of forming a plurality of filaments according to an embodiment.

FIG. 10 shows a Hastelloy substrate with grooves formed in a 2LUPS process with a CC stack 1038.

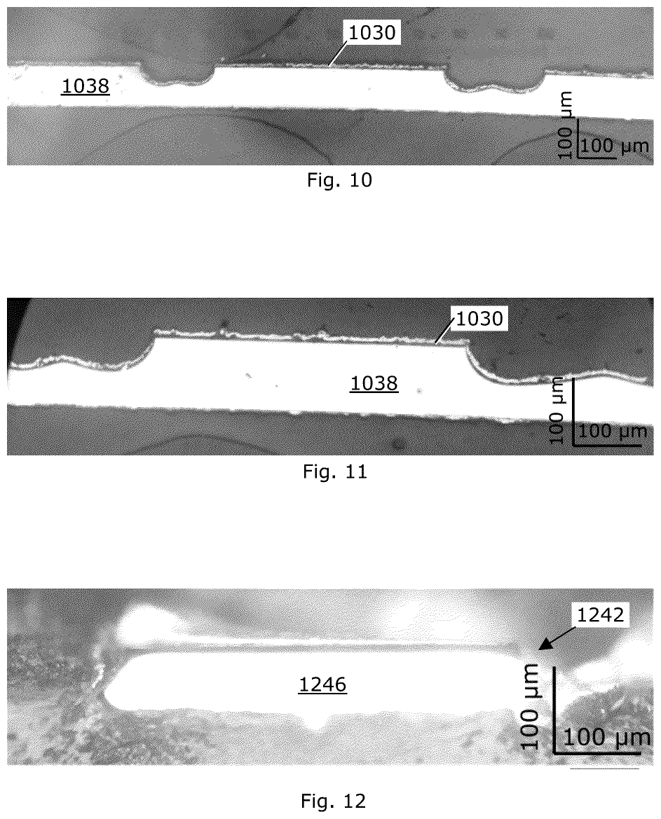

FIG. 11 shows a zoom view of FIG. 10.

FIG. 12 shows a single filament 1242 etched out.

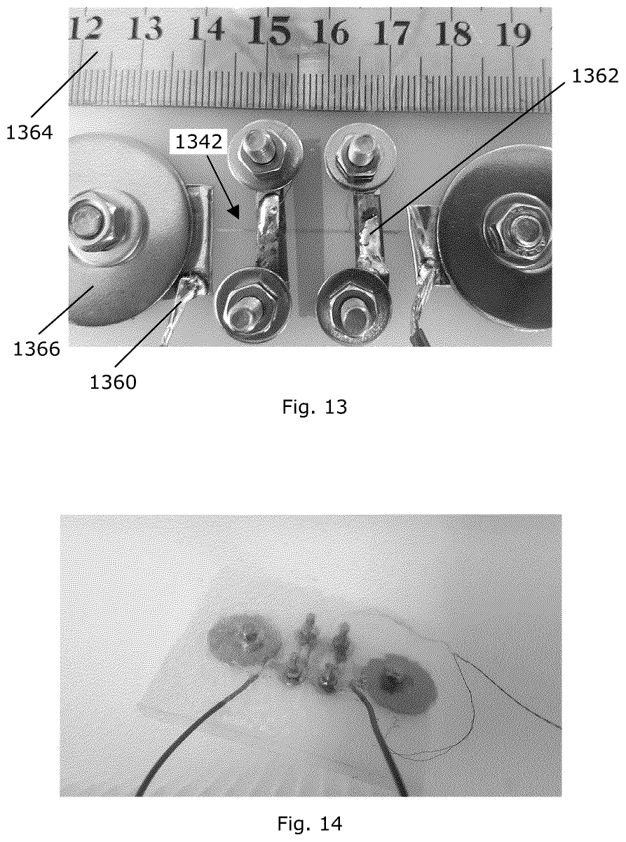

FIG. 13 shows I/V setup for characterizing superconducting performance of a filament.

FIG. 14 shows the I/V setup of FIG. 13 immersed in liquid nitrogen.

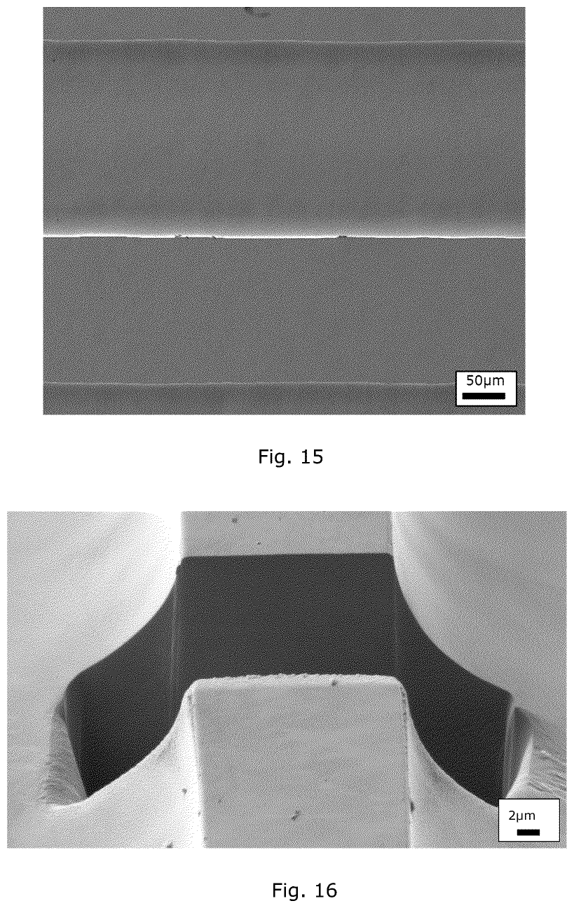

FIGS. 15-16 show Scanning Electron Microscope (SEM) images of 3D etched Hastelloy substrate.

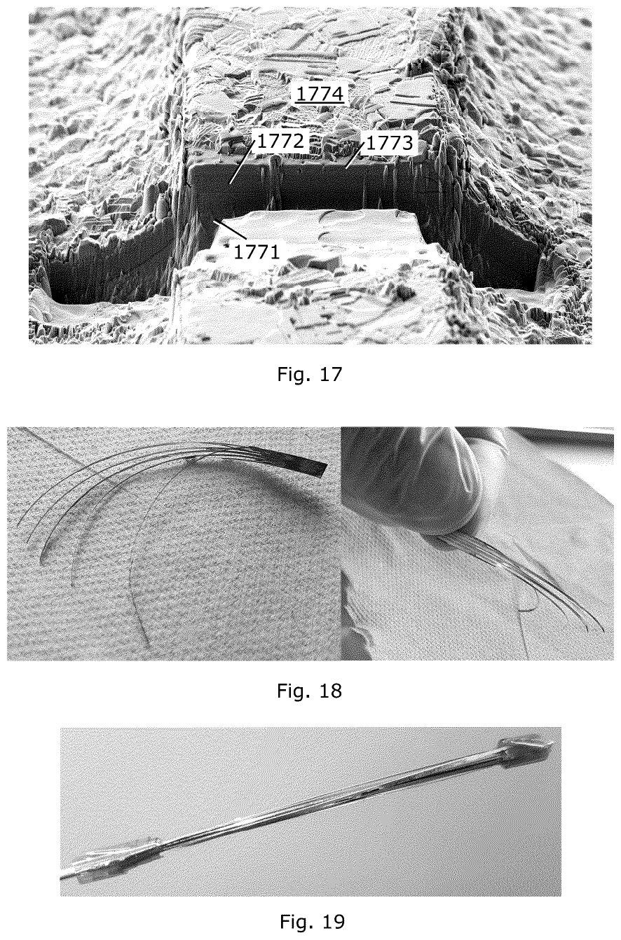

FIG. 17 shows Scanning Electron Microscope image of Focused Ion Beam milled HTS stack deposited on a 3D etched Hastelloy substrate.

FIG. 18 shows a collage of two images of filaments.

FIG. 19 shows the result of twisting a plurality of filaments.

### DETAILED DISCLOSURE OF THE INVENTION

FIG. 1 is a flowchart illustrating a method according to an embodiment of the invention, said method being a method 100 for forming a plurality of filaments, wherein each filament is superconducting, such as high-temperature superconducting (HTS), and furthermore forming a superconducting structure and providing a superconducting wire, said method sequentially comprising:
Providing 102 a substrate being a planar metal substrate, wherein the substrate has a first side and a second side, such as wherein the first side is opposite the second side, wherein providing the substrate comprises:
   i. Providing the substrate without grooves in the first side of the substrate,
   ii. forming 104 a plurality of grooves in the first side of the substrate, and
   iii. forming 106 via etching and/or electropolishing, and optionally in a two-level undercut process (2LUPS), one or more undercuts at each groove (although it is noted that alternative embodiments are conceivable, such as embodiments being similar in all other regards to the present embodiment, but wherein undercuts are not present or formed),
Applying 108 on the substrate a coating, wherein the coating is comprising a high-temperature superconductor stack, so that for each groove within the plurality of grooves,
   i. a first part of the coating on a first side of a feature of the groove, such as the groove,
   is separated, such as disconnected, such as physically disconnected, from
   ii. a second part of the coating on a second side of the feature of the groove, such as the groove, wherein the second side of the feature of the groove is opposite of the first side of the feature of the groove,
Applying 110 on some or all of the first part of the coating and on some or all of the second part of the coating, such as on the first part and/or the second part of the coating, a protective covering, such as a resist, wherein the protective covering partially or wholly fills vacant space in the grooves,
Removing 112 from the second side of the substrate via electropolishing and/or etching at least a part of the substrate, so as to remove at least a connection from the first part of the coating to the second part of the coating via the substrate, such as to provide the plurality of filaments, such as wherein portions of the substrate previously joining the filaments have been removed,
Stopping 114 the removing from the second side of the substrate at least a part of the substrate, while each part of the coating, such as the first part of the coating and the second part of the coating, is adjoining a remaining part of the substrate,
Removing 116 the protective covering partially or wholly from some or all of the coating and remaining portions of the substrate, such as so as to remove at least a connection from the first part of the coating to the second part of the coating via the protective covering,
Twisting 118 the plurality of filaments, or multiple pluralities of filaments, wherein each filament is twisted around its own axis and/or wherein a plurality of filaments are twisted around their common axis, such as wherein optionally twisted bundles of filaments are twisted around each other, thereby providing one or more superconducting structures each comprising a plurality of twisted filaments, such as wherein each filament has a helical shape with a center axis within one or more other helical shaped filaments,
Forming 120 a superconducting wire by providing one or more superconducting structures with a core and a capping.

FIGS. 2-7 shows schematic illustrations depicting steps in a method according to an embodiment of the invention, said method being a method 100 for forming a plurality of filaments, wherein each filament is superconducting, such as high-temperature superconducting (HTS), and furthermore forming a superconducting structure and providing a superconducting wire.

FIG. 2 shows 102 a substrate 228 being a planar metal substrate without grooves in the first side, wherein the substrate has a first side 231 and a second side 232, such as wherein the first side is opposite the second side.

FIG. 3 shows the substrate 230 after forming 104 a plurality of grooves 234 in the first side of the substrate, and after forming 106 one or more undercuts 236 at each groove (as indicated by the dashed lines delimiting the shadowed, undercut portions of each groove).

FIG. 3 also illustrates dimensions of the grooves 234. FIG. 3 is indicated a distance 233a between a plane (as indicated with the upper horizontal dashed line) being parallel with an (upper (in the figure)) surface of the first side of the substrate, such as being tangential with the protrusions between the grooves 234, and a plane (as indicated with the lower horizontal dashed line) and a plane being tangential to the bottom of the plurality of grooves, i.e., a depth of the grooves as measured in a direction orthogonal to the plane of the first side of the substrate (i.e., measured in the vertical/up-down direction in the plane of the paper of the figure). Said distance 233a or depth is non-zero, such as at least 100 nm, such as at least 1 μm, such as at least 10 μm, such as at least 25 μm, such as at least 50 μm, such as at least 100 μm. Said distance 233a or depth may furthermore be at most 4 mm, such as at most 2 mm, such as at most 1 mm. Said distance 233a or depth may be within ]10 nm; 4 mm[, such as within ]1 μm; 2 mm[, such as within ]10 μm; 1 mm[(where the open brackets “]x,;y[indicate that neither x nor y is included in the interval, yet all numbers therebetween are included). Furthermore is indicated a dimension or width 233b of the grooves, i.e., the distance from an edge (such as the beginning of an edge, such as the end of the planar portion of the substrate outside of the groove) of a protrusion on one side of groove to an edge of a protrusion on another side of a groove as measured in a direction parallel with the plane of the first side of the substrate and orthogonal to a longitudinal direction of the grooves (i.e., measured in the horizontal and left-right direction in the plane of the paper of the figure). The dimension or width 233b may be at least 1 micrometer, such as at least 2 micrometer, such as at least 5 micrometer, such as at least 10 micrometer, such as at least 3 0micrometer, such as at least 100 micrometer, such as at least 200 μm. The dimension or width 233b may be at most 1 mm, such as at most 500 μm, such as at most 200 μm, such as at most 100 μm. The dimension or width 233b may be within 1 micrometer-1 mm, such as within 10 μm-500 μm. There is in FIG. 3 furthermore indicated a distance 233c between adjacent grooves which is measured in the same direction as the width 233b. The distance 233c may be at least 100 μm. The distance 233c may be at most 2 mm. The distance 233c may be within ]100 μm; 2 mm[, such as within ]200 μm; 1 mm[.

FIG. 4 shows the substrate 230 after applying 108 on the substrate a coating 238 comprising a high-temperature superconductor stack, so that for each groove within the plurality of grooves a first part of the coating on a first side of the groove is physically disconnected, from a second part of the coating on a second side of the groove, wherein the second side of the feature of the groove is opposite of the first side of the feature of the groove. Furthermore, portions of coating material can be seen in the grooves.

FIG. 5 shows the substrate 230 Applying 110 on some or all of the first part of the coating and on some or all of the second part of the coating, such as on the first part and/or the second part of the coating, a protective covering 240, being a resist, wherein the protective covering partially or wholly fills vacant space in the grooves.

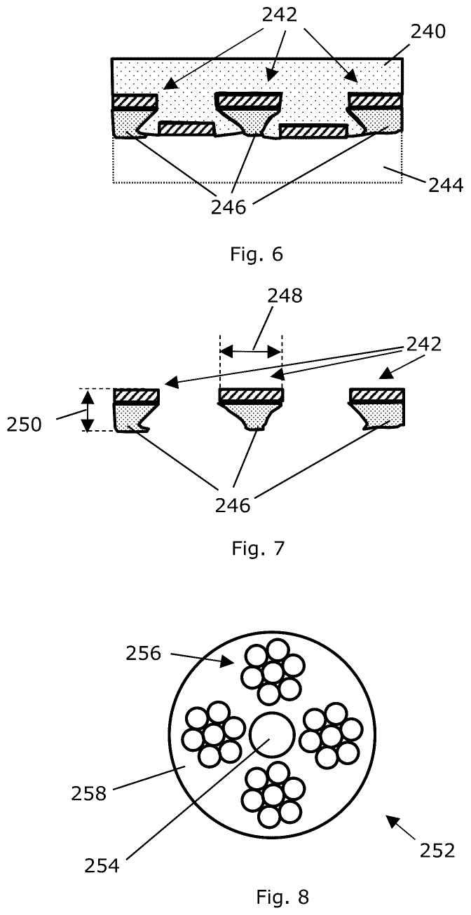

FIG. 6 shows the a plurality of filaments 242 after removing 112 from the second side of the substrate (where the substrate 230 is no longer present, and where dotted rectangle 244 indicates the position previously held by substrate 230) via electropolishing and/or etching at least a part of the substrate, so as to remove at least a connection from the first part of the coating to the second part of the coating via the substrate, such as so as to provide the plurality of filaments 242 wherein each filament is superconducting, such as wherein portions of the substrate previously joining the filaments have been removed, such as via the superconducting coating. FIG. 6 also shows the result of stopping 114 the removing from the second side of the substrate at least a part of the substrate, while each part of the coating, such as the first part of the coating and the second part of the coating, is adjoining a remaining part 246 of the substrate.

FIG. 7 shows the plurality of filaments 242 after removing 116 the protective covering 240 partially or wholly from some or all of the coating and remaining portions of the substrate, such as so as to remove at least a connection from the first part of the coating to the second part of the coating via the protective covering. FIG. 7 also indicates a width 248 and a thickness 250 of a filament. Length is a dimension orthogonal to the plane of the paper.

FIG. 8 shows a plurality of groups of filaments, wherein each filament is twisted around its own axis and wherein a plurality of filaments in each group of filaments are twisted around their common axis thereby providing a plurality of superconducting structures 256 each comprising a plurality of twisted filaments wherein each filament has a helical shape and wherein these superconducting structures have been provided 120 in a superconducting wire 252 with a core 254 and a capping 258.

### Example

According to an embodiment, there is presented a method of forming a plurality of filaments, wherein each filament is superconducting, said method comprising steps 1-9 as described in detail below (and schematically illustrated in FIG. 9):

A substrate which comprises a plurality of grooves is provided in steps 1-5, with forming the plurality of grooves in a first side (such as an over-side, a top side or a frontside) of the substrate in steps 2-5 (with the first side being opposite a second side, such as an under-side, a bottom side or a backside):

Step 1: Start with a substrate without grooves in the form of a polished 4 mm wide, 100 μm thick and 50 m long Hastelloy tape with surface roughness below 10 nm (where surface roughness is arithmetic surface roughness value over a 10×10 μm² atomic force microscopy scan). The surface quality is suitable for coated conductor (CC) chemical vapor deposition (CVD)/metal organic chemical vapor deposition (MOCVD), physical vapor deposition (PVD) or chemical deposition of buffer layers and superconducting layer. Polishing can be achieved by electrochemical polishing in a solution of phosphorous and sulfuric acid mixture following standard procedures from the literature, see, e.g., Wulff et al. 2015, Supercond. Sci. Technol. 28(2015) 072001, page 2, section 2.

Subfigure (a) of FIG. 9 shows a cross-sectional view of the tape in a plane being orthogonal to a longitudinal direction of the tape.

Step 2: Apply a masking material as described in Wulff et al. 2015, Supercond. Sci. Technol. 28 (2015) 072001, page 2, section 2.

This could be a masking tape, such as a Kapton® film, a photoresist or similar. It is understood that ‘Kapton® film’ refers to the well-known product from DuPont™ which is a film of poly(4,4′-oxydiphenylene-pyromellitimide).

Subfigure (b) of FIG. 9 shows a cross-sectional view of the tape in a plane being orthogonal to a longitudinal direction of the tape with masking material.

Step 3: Remove part of the masking material using mechanical scribing, a wet/dry chemical lithography process, or by laser scribing. Here it is done using standard lithography steps to fully remove the masking material in areas where grooves are to be etched.

Subfigure (c) of FIG. 9 shows a cross-sectional view of the tape in a plane being orthogonal to a longitudinal direction of the tape with part of the masking material removed.

Step 4: Etch into the substrate using a mixture of phosphorous and sulfuric acid applying a current density between 0.01-1 A/cm² until grooves have been formed.

Subfigure (d) of FIG. 9 shows a cross-sectional view of the tape in a plane being orthogonal to a longitudinal direction of the tape with grooves formed by etching.

Step 5: Remove the masking material using an organic solvent (such as acetone) or a stripping agent such as sodium hydroxide.

Applying on the substrate a coating, wherein the coating (coated conductor (CC) stack) is a high-temperature superconductor stack, so that for each groove within the plurality of grooves, a first part of the coating on a first side of the groove, is separated (such as separated, but still physically connected, e.g., as depicted in FIG. 9(e)), from a second part of the coating on a second side of the groove, wherein the second side of the feature of the groove is opposite of the first side of the feature of the groove, is carried out in step 6.

Step 6: Deposit a superconducting coated conductor (CC) stack on the material, cf., e.g., a method as described in Wulff et al 2015, Supercond. Sci. Technol. 28 (2015) 072001, page 2, section 2, or Insinga et al 2018, IEEE TRANSACTIONS ON APPLIED SUPERCONDUCTIVITY, VOL. 28, NO. 4, June 2018, page 2, section 2.

Subfigure (e) of FIG. 9 shows a cross-sectional view of the tape in a plane being orthogonal to a longitudinal direction of the tape with the remaining parts of the masking material removed and a superconducting CC stack deposited on the tape.

Applying on some or all of the first part of the coating and on some or all of the second part of the coating a protective covering (protective material), which partially or wholly fills vacant space in the grooves is carried out in step 7.

Step 7: Apply a protective material, such as liquid photoresist and cover the top (and in this embodiment also covering the sides, such as to avoid etching of the sides of the substrate and/or the sides of the outer CC stacks) of the tape and CC stack so as to protect the superconducting stack. The grooves should also be fully or partly covered with protective material. The protective material can be applied in several ways, e.g., liquid photoresist applied with an inkjet (e.g., with an opposite side of the tape held firmly against a solid element to avoid photoresist on said opposite side), with a brush or with dip-coating (such as dip-coating with an opposite side of the tape temporarily covered, e.g., with Scotch tape®).

Subfigure (f) of FIG. 9 shows a cross-sectional view of the tape in a plane being orthogonal to a longitudinal direction of the tape with the protective material applied.

Removing from the second side (such as the backside or bottom side) of the substrate via etching, such as electrochemical etching, or via electropolishing, at least a part of the substrate, so as to remove at least a connection from the first part of the coating to the second part of the coating via the substrate, such as so as to provide the plurality of filaments, wherein portions of the substrate previously joining the filaments have been removed, is carried out in step 8.

Step 8: Etch from the backside of the tape structure using mixture of phosphorous and sulfuric acid. Etching can be continued until these are only physically connected via the protective material.

Subfigure (g) of FIG. 9 shows a cross-sectional view of the resulting plurality of filaments, which are being connected by the protective covering in a plane being orthogonal to a longitudinal direction of the plurality of filaments (same view as in subfigure (g) of FIG. 9) after a portion of the substrate has been removed from the backside.

Removing the protective covering partially or wholly from some or all of the coating and remaining portions of the substrate, such as so as to remove at least a connection from the first part of the coating to the second part of the coating via the protective covering is carried out in step 9.

Step 9: The protective material is removed either mechanically by peeling off the material, or dissolving in an organic solvent, such as ethanol or acetone, or a stripping solvent such as sodium hydroxide.

Subfigure (h) of FIG. 9 shows a cross-sectional view of the resulting plurality of filaments, which are no longer being connected by the protective covering in a plane being orthogonal to a longitudinal direction of the plurality of filaments, i.e., after the protective covering has been removed.

FIG. 10 shows a Hastelloy substrate 1030 with grooves formed in a 2LUPS process with a CC stack 1038 (without undercut). FIG. 10 could be seen as corresponding to the schematic illustrations in FIG. 4 and/or subfigure (e) of FIG. 9.

FIG. 11 shows a zoom view of FIG. 10.

FIG. 12 shows a single filament 1242 etched out, but with a remaining part 1246 of substrate, where a width (i.e., a size in a horizontal dimension left-right, i.e., in the plane of the paper, being ca. 500 μm, i.e., the image depicts a ca. 500 μm wide filament 1242 with CC stack). A thickness (dimension up-down in the plane of the paper) of the filament is ca. 80 μm. FIG. 12 could be seen as corresponding to the schematic illustrations in FIG. 7 and/or subfigure (h) of FIG. 9.

FIG. 13 shows I/V setup for characterizing superconducting performance of a filament 1342 in liquid nitrogen, including current lead 1360 and voltage tap 1362. The dimensions can be retrieved from the ruler 1364 (with numbers being centimeters and the distance between adjacent smaller line markings being 1 mm). The washer 1366 is substantially circular, which indicates that the scale provided by the ruler applies both horizontally and vertically.

FIG. 14 shows the I/V setup of FIG. 13 immersed in liquid nitrogen. An electrical current ramping test with the filament immersed in liquid nitrogen while measuring the voltage drop between the contacts points showed no transition to normal conducting at more than 3 A at zero applied magnetic field and 77 K. With a width of estimated 500 μm and a total thickness of estimated 80 μm of the substrate and CC stack, an engineering current density of 9375 A/cm² at zero applied magnetic field and 77 K is estimated. A reference coated conductor sample had a recorded average Ic=97 A at zero applied magnetic field at 77 K for a 4 mm tape width corresponding to an expected Ic for the 500 μm wide filament of more than 12 A. It is noted that an engineering current density could be improved with a factor of at least 3-5 with another choice of superconducting material. Furthermore, a (such as another) factor of at least 2 could be achieved by reducing a thickness of the substrate, such as by continuing for a longer time the etch removing the substrate from the backside (such as giving substrate being, e.g., less than half the thickness of the present substrate), such as a factor of approximately 20 by leaving only a small part of the substrate (about 4 μm in thickness), such as estimated with a situation where the substrate is etched away completely. Taking both the possible improvement in materials and reduced substrate thickness into account, an engineering current density of approximately 1,8 MA/cm² may be arrived at zero magnetic field and 77 K. It is also noted that additionally higher current densities at expected at decreased operating temperatures, such as 50 K, such as 30 K, such as 20 K or 4.2 K. In contrast, lower current densities are expected at increased applied magnetic fields.

FIG. 15 shows Scanning Electron Microscope (SEM) image (view: normal to tape flat surface) of 3D etched Hastelloy substrate. FIG. 15 could be seen as corresponding to the schematic illustration in FIG. 3 (except for the undercut) and/or subfigure (d) of FIG. 9 (except for the remaining masking material).

FIG. 16 shows Scanning Electron Microscope image (view: angled) of 3D etched and Focused Ion Beam milled 3D etched Hastelloy substrate. The figure shows a protrusion (or elongated “hill”) formed between two grooves (on the left and right side of the protrusion), where the protrusion has a width (left-right in the plane of the paper) of ca. 18 μm. FIG. 16 (except for the Focused Ion Beam milled cut-out) could be seen as corresponding to the schematic illustrations in FIG. 3 (except for the undercut) and/or subfigure (d) of FIG. 9 (except for the remaining masking material).

FIG. 17 shows Scanning Electron Microscope image of Focused Ion Beam milled 3D etched Hastelloy substrate with CC stack in the form of a substrate 1771 being Hastelloy C276, a 1-2 μm thick buffer layer 1772 being Yttria-stabilized zirconia (YSZ) with 50 nm Cerium Oxide (as in Wulff et al. 2015, Supercond. Sci. Technol. 28 (2015) 072001), a 1-2 um thick layer 1773of Yttrium barium copper oxide (YBCO) layer and a silver layer 1774 being 1-2 μm thick. All thicknesses refer to a dimension in the vertical/up-down direction in the figure, i.e., orthogonal to the plane of the respective layers. Width of the superconducting filament is ca. 25 μm. FIG. 17 could be seen as corresponding to the schematic illustrations in FIG. 4 (except for the undercut) and/or subfigure (c) of FIG. 9.

FIG. 18 shows a collage of two images of filaments (with the filaments in the image on the right side being held by a human hand), where a substrate has been etched from the backside so as to remove a connection between the filaments through the substrate in a plane orthogonal to a longitudinal direction of the substrates. A length of the filaments, such as the free portion of the filaments, spans several centimeters. The (full) width of the substrate is 4 mm (such as the full width shown in the up-down direction in the upper right corner of the left sub-figure).

FIG. 19 shows the result of twisting a plurality of filaments wherein the plurality of filaments is twisted around their common axis and wherein each filament is thereby also twisted around its own axis (by an angular amount corresponding to the twisting of the plurality of filaments) thereby providing a structure comprising a plurality of twisted filaments wherein each filament is twisted around its own axis and furthermore has a helical shape with a center axis within one or more other helical shaped filaments, and wherein a wire has been provided by providing a core. Kapton® tape is provided in each end, and a distance between the Kapton® tapes is 5 cm.

Although the present invention has been described in connection with the specified embodiments, it should not be construed as being in any way limited to the presented examples. The scope of the present invention is set out by the accompanying claim set. In the context of the claims, the terms “comprising” or “comprises” do not exclude other possible elements or steps. Also, the mentioning of references such as “a” or “an” etc. should not be construed as excluding a plurality. The use of reference signs in the claims with respect to elements indicated in the figures shall also not be construed as limiting the scope of the invention. Furthermore, individual features mentioned in different claims, may possibly be advantageously combined, and the mentioning of these features in different claims does not exclude that a combination of features is not possible and advantageous.

### Clauses

There is furthermore presented a method for forming a plurality of filaments, a plurality of filaments and use of the plurality of filaments according to the clauses below, which clauses may be combined with any of the preceding embodiments and/or any of the appended claims:

1. A method (100) for forming a plurality of filaments (242), wherein each filament is superconducting, such as high-temperature superconducting (HTS), said method comprising, such as sequentially comprising:
Providing (102) a substrate (230), such as wherein the substrate comprises metal, such as the substrate being a planar metal substrate, wherein the substrate has a first side (231) and a second side (232), such as wherein the first side is opposite the second side, and wherein the substrate comprises a plurality of grooves (234) in the first side of the substrate,
Applying (108) on the substrate a coating (238), wherein the coating is comprising a superconducting material, such as said coating being a high-temperature superconductor stack, so that for each groove within the plurality of grooves,
   i. a first part of the coating on a first side of a feature of the groove, such as the groove,
   is separated, such as disconnected, such as physically disconnected, from
   ii. a second part of the coating on a second side of the feature of the groove, such as the groove, wherein the second side of the feature of the groove is opposite of the first side of the feature of the groove,
Removing (112) from the second side of the substrate, such as via electropolishing and/or etching, at least a part of the substrate, so as to remove at least a connection from the first part of the coating to the second part of the coating via the substrate, such as so as to provide the plurality of filaments, such as wherein portions of the substrate previously joining the filaments have been removed.

2. A method (100) according to any of the preceding clauses, further comprising prior to removing from the second side of the substrate at least a part of the substrate:
Applying (110) on some or all of the first part of the coating and on some or all of the second part of the coating (238), such as on the first part and/or the second part of the coating, a protective covering (240), such as a resist, such as a protective covering layer, such as wherein the protective covering layer partially or wholly fills vacant space in the grooves.

3. A method (100) according to any of the preceding clauses, wherein removing from the second side (232) of the substrate (230) at least a part of the substrate is carried out via electropolishing and/or etching, such as electro-etching.

4. A method (100) according to any of the preceding clauses, wherein the removing from the second side of the substrate at least a part of the substrate, such as the electropolishing and/or etching, is stopped (114) while each part of the coating, such as the first part of the coating and the second part of the coating, is adjoining a remaining part (246) of the substrate.

5. A method (100) according to any of the preceding clauses, wherein the method is further comprising:
Twisting (118) the plurality of filaments (242), or multiple pluralities of filaments, wherein each filament is twisted around its own axis and/or wherein a plurality of filaments are twisted around their common axis, such as wherein optionally twisted bundles of filaments are twisted around each other, thereby providing one or more superconducting structures (256) each comprising a plurality of twisted filaments, such as wherein each filament has a helical shape with a centre axis within one or more other helical shaped filaments, and/or
Transposition of the plurality of filaments (242), or multiple pluralities of filaments thereby providing one or more superconducting structures (256) each comprising a plurality of transposed filaments.

6. A method (100) according to clause 5, wherein the method is further comprising:
Forming (120) a superconducting wire (252) by providing one or more superconducting structures (256) with a core (254) and/or a capping (258).

7. A plurality of filaments (242), wherein each filament is superconducting, such as high-temperature superconducting (HTS), and wherein each filament is not being connected to the one or more other filaments via the substrate, such as wherein each filament is physically disconnected from one or more other parts of the substrate.

8. The plurality of filaments according to clause 7, wherein each filament is comprising superconducting material, such as high-temperature superconducting (HTS) material, and furthermore comprising a part of the substrate adjoining the superconducting material.

9. The plurality of filaments (242) according to any of clauses 7-8, wherein the substrate is roll-processed, such as metal or metal-alloy, such as Hastelloy, stainless steel, an austenitic nickel-chromium-based superalloys, such as Inconel®, or nickel-tungsten.

10. The plurality of filaments (242) according to any of clauses 7-9, wherein the plurality of filaments are connected by a protective covering (240), and where the protective covering is only partially covering each filament.

11. The plurality of filaments (242) according to any of clauses 7-10, wherein a width (248), such as a maximum dimension in a direction orthogonal to a longitudinal direction of each filament and optionally furthermore being parallel with an interface between superconducting material and substrate material, of each filament is equal to or less than 200 micrometer, such as equal to or less than 150 micrometer, such as equal to or less than 100 micrometer, such as equal to or less than 50 micrometer, such as equal to or less than 25 micrometer, such as equal to or less than 10 micrometer.

12. The plurality of filaments (242) according to any of clauses 7-11, wherein a length, such as a maximum dimension in a longitudinal direction of each filament, of each filament is equal to or larger than 1 m, such as equal to or larger than 10 m, such as equal to or larger than 100 m, such as equal to or larger than 1 km, such as equal to or larger than 10 km, such as equal to or larger than 100 km, such as equal to or larger than 1000 km.

13. The plurality of filaments (242) according to any of clauses 7-12, wherein an engineering current density JE of each filament at a temperature of 77 Kelvin and at zero applied magnetic field is at least 10³ A/cm², such as at least 3*10³ A/cm², such as at least 10⁴ A/cm², such as at least 18750 A/cm², such as at least 3*10⁴ A/cm², such as at least 10⁵ A/cm², such as at least 3*10⁵ A/cm², such as at least 5*10⁵ A/cm², such as at least 10⁶ A/cm², such as at least 3*10⁶ A/cm², such as at least 10⁷ A/cm², wherein the engineering current density is defined as the current density for a cross-sectional area including superconducting material and substrate including if present buffer layer or buffer-stack and stabilizing layer, wherein each filament is optionally having a width being equal to or less than 500 micrometer, such as equal to or less than 400 micrometer.

14. The plurality of filaments (242) according to any of clauses 7-13, wherein a distance, such as an average distance, from an edge, such as an edge at a side, of the filament and into the filament, wherein superconducting properties of the superconducting material has deteriorated, is equal to or less than 100 micrometer, such as equal to or less than 50 micrometer, such as equal to or less than 25 micrometer, such as equal to or less than 20 micrometer, such as equal to or less than 15 micrometer, such as equal to or less than 10 micrometer, such as equal to or less than 5 micrometer.

15. Use of the plurality of filaments (242) as provided according to any of clauses 1-6 and/or according to any of clauses 7-14 for conducting a current, such as conducting a current at superconducting conditions.

1.-33. (canceled)

34. A method for forming a plurality of filaments, wherein each filament is superconducting, said method comprising, such as sequentially comprising:
providing a substrate, such as wherein the substrate comprises metal, such as the substrate being a planar metal substrate,
wherein the substrate has a first side and a second side, such as wherein the first side is opposite the second side, and
wherein the substrate comprises a plurality of grooves in the first side of the substrate,
applying on the substrate a coating, wherein the coating is comprising a superconducting material, such as said coating being a high-temperature superconductor stack, so that for each groove within the plurality of grooves,
i. a first part of the coating on a first side of a feature of the groove, such as the groove,
is separated, such as disconnected, such as physically disconnected, from
ii. a second part of the coating on a second side of the feature of the groove, such as the groove, wherein the second side of the feature of the groove is opposite of the first side of the feature of the groove,
removing from the second side of the substrate, such as via electropolishing and/or etching, at least a part of the substrate, so as to remove at least a connection from the first part of the coating to the second part of the coating via the substrate, such as so as to provide the plurality of filaments, such as wherein portions of the substrate previously joining the filaments have been removed.

35. The method according to claim 34, further comprises prior to removing from the second side of the substrate at least a part of the substrate:
applying on some or all of the first part of the coating and on some or all of the second part of the coating, such as on the first part and/or the second part of the coating, a protective covering, such as a resist, such as a protective covering layer, such as wherein the protective covering layer partially or wholly fills vacant space in the grooves.

36. The method according to claim 34, wherein removing from the second side of the substrate at least a part of the substrate is carried out via electropolishing and/or etching, such as electro-etching.

37. The method according to claim 36, wherein the electropolishing and/or etching is stopped before a liquid utilized for said electropolishing and/or etching reaches the first part of the coating and/or the second part of the coating.

38. The method according to claim 34, wherein removing from the second side of the substrate at least a part of the substrate is carried out via grinding and/or laser.

39. The method according to claim 34, wherein the removing from the second side of the substrate at least a part of the substrate, such as the electropolishing and/or etching, is stopped while each part of the coating, such as the first part of the coating and the second part of the coating, is adjoining a remaining part of the substrate.

40. The method according to claim 34, wherein the method is further comprising:
twisting the plurality of filaments, or multiple pluralities of filaments,
wherein each filament is twisted around its own axis and/or
wherein a plurality of filaments are twisted around their common axis, such as wherein optionally twisted bundles of filaments are twisted around each other, thereby providing one or more superconducting structure each comprising a plurality of twisted filaments, such as wherein each filament has a helical shape with a center axis within one or more other helical shaped filaments, and/or
transposition of the plurality of filaments, or multiple pluralities of filaments thereby providing one or more superconducting structures each comprising a plurality of transposed filaments.

41. The method according to claim 34, wherein the method is further comprising:
forming a superconducting wire by providing one or more superconducting structures with a core and/or a capping.

42. The method according to claim 34, wherein a distance between a plane being parallel with a surface of the first side of the substrate, such as being tangential with the protrusions between the grooves, and a plane being tangential to a bottom of the plurality of grooves, such as a depth of the grooves as measured in a direction orthogonal to the plane of the first side of the substrate, is at least 1 μm.

43. The method according to claim 34, wherein providing a substrate comprises providing the substrate, such as a tape, in a reel-to-reel setup.

44. The method according to claim 34, wherein applying on the substrate a coating comprises applying on the substrate, such as a tape, a coating in a reel-to-reel setup.

45. The method according to claim 34, wherein removing from the second side of the substrate at least a part of the substrate comprises removing from the second side of the substrate at least a part of the substrate, such as a tape, in a reel-to-reel setup.

46. The method according to claim 34, wherein each groove in the plurality of grooves comprises one or more undercuts.

47. The method according to claim 34, said method comprising:
forming, such as via etching, one or more undercuts at each groove.

48. A plurality of filaments, wherein each filament is superconducting, such as high-temperature superconducting (HTS), and
wherein each filament is not being connected to the one or more other filaments via the substrate, such as
wherein each filament is physically disconnected from one or more other parts of the substrate.

49. The plurality of filaments, wherein each filament is superconducting, such as high-temperature superconducting (HTS), and
wherein each filament is not being connected to the one or more other filaments via a substrate, such as
wherein each filament is physically disconnected from one or more other parts of the substrate.

50. The plurality of filaments according to claim 48, where each filament comprises a substrate.

51. The plurality of filaments according to claim 48, wherein the substrate is a solid element upon which a superconducting material may be placed, such as deposited, so that the substrate and the superconducting element may together form a superconducting element.

52. The plurality of filaments according to claim 51, wherein the solid element comprises a material selected from the group comprising: a nickel-based alloy, a copper based alloy, a chrome based alloy, iron, aluminum, silicon, titanium, tungsten (also known as wolfram (W)), silver, Hastelloy, Inconel® and stainless steel.

53. The plurality of filaments according to claim 48, wherein each filament is comprising superconducting material comprising, such as consisting of rare-earth barium copper oxide.

54. The plurality of filaments according to claim 48, wherein each filament is comprising superconducting material, such as high-temperature superconducting (HTS) material, and furthermore comprising a part of the substrate adjoining the superconducting material.

55. The plurality of filaments according to claim 54, wherein each filament comprises superconducting material on, such as partially or fully covering each of, two or more sides of the substrate, such as
wherein each of said sides are non-parallel, such as orthogonal, with respect to at least one other side within the two or more sides as observed in a cross-sectional view orthogonal to a longitudinal direction of each of the filament.

56. The plurality of filaments according to claim 54, wherein an angular extent of the superconducting material as observed in a cross-sectional view orthogonal to a longitudinal direction of each of the filament around a geometrical center of the substrate is 90° or more.

57. The plurality of filaments according to claim 48, wherein the substrate is roll-processed, such as metal or metal-alloy, such as Hastelloy, stainless steel, an austenitic nickel-chromium-based superalloys, such as Inconel®, or nickel-tungsten.

58. The plurality of filaments according to claim 48, wherein the plurality of filaments are connected by a protective covering, and where the protective covering is only partially covering each filament.

59. The plurality of filaments according to claim 48, wherein a width, such as a maximum dimension in a direction orthogonal to a longitudinal direction of each filament and optionally furthermore being parallel with an interface between superconducting material and substrate material, of each filament is equal to or less than 200 micrometer.

60. The plurality of filaments according to claim 48, wherein a width, such as a maximum dimension in a direction orthogonal to a longitudinal direction of each filament and optionally furthermore being parallel with an interface between superconducting material and substrate material, of each filament is equal to or more than 1 micrometer.

61. The plurality of filaments according to claim 48, wherein a length, such as a maximum dimension in a longitudinal direction of each filament, of each filament is equal to or larger than 1 m.

62. The plurality of filaments according to claim 48, wherein a thickness, such as a maximum dimension in a direction orthogonal to a longitudinal direction of each filament and optionally furthermore being orthogonal to an interface between superconducting material and substrate material, such as wherein said dimension is being orthogonal to one or both of the dimensions along which width and length are measured, is at least 1 μm.

63. The plurality of filaments according to claim 48, wherein an engineering current density JE of each filament at a temperature of 77 Kelvin and at zero applied magnetic field is at least 103 A/cm2,
wherein the engineering current density is defined as the current density for a cross-sectional area including superconducting material and substrate including if present buffer layer or buffer-stack and stabilizing layer,
wherein each filament is optionally having a width being equal to or less than 500 micrometer.

64. The plurality of filaments according to claim 48, wherein a distance, such as an average distance, from an edge, such as an edge at a side, of the filament and into the filament, wherein superconducting properties of the superconducting material has deteriorated, is equal to or less than 100 micrometer.

65. A wire, provided according to claim 34.

66. Use of the plurality of filaments as provided according to claim 34 for conducting a current, such as conducting a current at superconducting conditions.
